(19) United States
(12) Patent Application Publication
(10) Pub. No.: US 2026/0048676 A1
(43) Pub. Date: Feb. 19, 2026

(54) VEHICLE CONTROL APPARATUS AND A BATTERY CHARGING CONTROL METHOD

(71) Applicants: HYUNDAI MOTOR COMPANY, Seoul (KR); KIA CORPORATION, Seoul (KR); Auburn University, Auburn, AL (US)

(72) Inventors: Wooju Lee, Hwaseong-si (KR); Song-Yul Choe, Auburn, AL (US); Kyungjin Yu, Daegu (KR)

(73) Assignees: HYUNDAI MOTOR COMPANY, Seoul (KR); KIA CORPORATION, Seoul (KR); Auburn University, Auburn, AL (US)

(21) Appl. No.: 19/287,627

(22) Filed: Jul. 31, 2025

Related U.S. Application Data
(60) Provisional application No. 63/683,009, filed on Aug. 14, 2024.

(30) Foreign Application Priority Data
Jun. 11, 2025 (KR) 10-2025-0076701

(51) Int. Cl. B60L 53/62; B60L 53/10; G01R 31/382; G01R 31/392; G01R 31/396

(52) U.S. Cl. CPC B60L 53/62; B60L 53/11; G01R 31/382; G01R 31/392; G01R 31/396

(57) ABSTRACT

A vehicle control apparatus includes a processor configured to optimize a battery model based on an optimization algorithm and generate a variable charging map based on the optimized battery model. The processor is also configured to obtain state information of a battery and determine an optimal charge current corresponding to the state information of the battery based on the variable charging map. The processor is further configured to control a charger to perform battery charging based on the determined optimal charge current.

### CROSS-REFERENCE TO RELATED APPLICATION

This application claims priority to and the benefit of U.S. Provisional Patent Application No. 63/683,009, filed on Aug. 14, 2024 and Korean Patent Application No. 10-2025-0076701, filed on Jun. 11, 2025, the entire contents of both of which are hereby incorporated herein by reference.

### TECHNICAL FIELD

The present disclosure relates to a vehicle control apparatus and a battery charging control method.

### BACKGROUND

The statements in this section merely provide background information related to the present disclosure and may not constitute prior art.

Lithium-ion batteries are important components, in terms of costs and performance, of electric vehicles and hybrid electric vehicles. The electric vehicle to which such a lithium-ion battery has a problem in which it takes a long time to charge the battery and mileage is limited. Thus, an existing technology shortens the charge time via charging at a high current rate (C-rate), but has a problem in which serious degradation and high heat generation are involved.

Recently, a multi-stage constant current (MCC) charging protocol has been developed for battery charging. The MCC charging protocol is an algorithm for controlling charging of the battery to limit overpotential to not exceed lithium plating (LiP) overpotential in only an initial state of the battery. As the battery degrades, lithium dendrites grow upon charging, which may lead to internal short circuits, thus reducing a margin for safe operation.

### SUMMARY

The present disclosure has been made to solve the above-mentioned problems occurring in the prior art while advantages achieved by the prior art are maintained intact.

Aspects of the present disclosure provide a vehicle control apparatus and a battery charging control method for optimizing a charge current and a cut-off voltage to reduce or minimize lithium plating, suppress heat generation, and shorten a charge time of a battery.

Other aspects of the present disclosure provide a vehicle control apparatus and a battery charging control method for optimizing a fast charging scheme based on (or using) a nonlinear model predictive control (NMPC) algorithm based on an electrochemical-thermal-life model.

The technical problems to be solved by the present disclosure are not limited to the aforementioned problems. Other technical problems not mentioned herein should be more clearly understood from the following description by those having ordinary skill in the art to which the present disclosure pertains.

According to an aspect of the present disclosure, a vehicle control apparatus is provided. The vehicle control apparatus includes a processor configured to optimize a battery model based on an optimization algorithm. The processor is also configured to generate a variable charging map based on the optimized battery model. The processor is further configured to obtain state information of a battery and determine an optimal charge current corresponding to the state information of the battery based on the variable charging map. The processor is additionally configured to control a charger to perform battery charging based on the determined optimal charge current.

The optimization algorithm may include a nonlinear model predictive control algorithm.

The battery model may include an electrochemical-thermal-life model.

The variable charging map may be a table in which an optimal charge current corresponding to a voltage and a state of health (SOH) of the battery is defined.

The processor may be configured to determine whether a current SOC of the battery is less than a fast charging upper limit SOC. The processor may also be configured to determine whether a current voltage of the battery is greater than or equal to a fast charging upper limit voltage, based on determining that the current SOC of the battery is less than the fast charging upper limit SOC. The processor may further be configured to reduce the charge current by a predetermined factor, based on determining that the current voltage of the battery is greater than or equal to the fast charging upper limit voltage.

The processor may be configured to determine whether an optimization algorithm start condition is satisfied, based on determining that the current voltage of the battery is not greater than or equal to the fast charging upper limit voltage. The processor may be configured to execute the optimization algorithm, based on determining that the optimization algorithm start condition is satisfied.

The processor may be configured to determine whether a constant current application time is greater than a constant current application end time and overpotential is less than allowable overpotential, and determine whether the optimization algorithm start condition is satisfied based on the determined result.

The processor may be configured to determine the optimal charge current in a predetermined constraint via the optimization algorithm.

The processor may be configured to maintain a previous charge current, based on determining that an optimization algorithm start condition is not satisfied.

The processor may be configured to obtain at least one of a voltage of the battery, a SOH of the battery, or any combination thereof, as the state information of the battery based on one or more signals obtained from one or more sensors installed in the battery.

According to another aspect of the present disclosure, a battery charging control method is provided. The battery charging control method includes optimizing a battery model based on an optimization algorithm and generating a variable charging map based on the optimized battery model. The battery charging control method also includes obtaining state information of a battery and determining an optimal charge current corresponding to the state information of the battery based on the variable charging map. The battery charging control method additionally includes controlling a charger to perform battery charging based on the determined optimal charge current.

The optimization algorithm may include a nonlinear model predictive control algorithm.

The battery model may include an electrochemical-thermal-life model.

The variable charging map may be a table in which an optimal charge current corresponding to a voltage and a state of health (SOH) of the battery voltage is defined.

Optimizing the battery model may include determining whether a current SOC of the battery is less than a fast charging upper limit SOC. Optimizing the battery model may also include determining whether a current voltage of the battery is greater than or equal to a fast charging upper limit voltage, based on determining that the current SOC of the battery is less than the fast charging upper limit SOC. Optimizing the battery model may additionally include reducing the charge current by a predetermined factor, based on determining that the current voltage of the battery is greater than or equal to the fast charging upper limit voltage.

Optimizing the battery model may include determining whether an optimization algorithm start condition is satisfied, based on determining that the current voltage of the battery is not greater than or equal to the fast charging upper limit voltage, and executing the optimization algorithm, based on determining that the optimization algorithm start condition is satisfied.

Determining whether the optimization algorithm start condition is satisfied may include determining whether a constant current application time is greater than a constant current application end time and overpotential is less than allowable overpotential, and determining whether the optimization algorithm start condition is satisfied based on the determined result.

Executing the optimization algorithm may include determining the optimal charge current in a predetermined constraint.

Optimizing the battery model may include maintaining a previous charge current, based on determining that an optimization algorithm start condition is not satisfied.

Obtaining the state information of the battery may include obtaining at least one of a voltage of the battery, a SOH of the battery, or any combination thereof, as the state information of the battery based on one or more signals obtained from one or more sensors installed in the battery.

### BRIEF DESCRIPTION OF THE DRAWINGS

The above and other objects, features, and advantages of the present disclosure should be more clearly understood from the following detailed description taken in conjunction with the accompanying drawings, in which:

FIG. 1 is a block configuration diagram illustrating a battery charging system according to embodiments of the present disclosure;

FIG. 2 is a block diagram schematically illustrating a fast charging scheme associated with embodiments of the present disclosure;

FIG. 3A is a schematic diagram illustrating a microcell associated with embodiments of the present disclosure;

FIG. 3B is a drawing illustrating a structure of an electrochemical-thermal-life model according to embodiments of the present disclosure;

FIG. 4 is a drawing illustrating electrochemical degradation mechanisms according to embodiments of the present disclosure;

FIG. 5A is a graph illustrating a battery state of health (SOH) of the result of verifying a degradation model associated with embodiments of the present disclosure;

FIG. 5B is a graph illustrating a capacity root mean square error (RMSE) of the result of verifying a degradation model associated with embodiments of the present disclosure;

FIG. 5C is a graph illustrating a voltage RMSE of the result of verifying a degradation model associated with embodiments of the present disclosure;

FIG. 6 is a flowchart illustrating a method for optimizing a fast charging algorithm according to embodiments of the present disclosure;

FIG. 7 illustrates the result of simulating an optimized multi-stage constant current (O-MCC) in an initial battery SOH interval according to embodiments of the present disclosure;

FIG. 8A illustrates a current graph of the result of simulating an O-MCC according to embodiments of the present disclosure;

FIG. 8B illustrates an overpotential graph of the result of simulating an O-MCC according to embodiments of the present disclosure;

FIG. 8C illustrates a voltage graph of the result of simulating an O-MCC according to embodiments of the present disclosure;

FIG. 8D illustrates a SOC graph of the result of simulating an O-MCC according to embodiments of the present disclosure;

FIG. 9A is a graph illustrating the result of comparing battery SOHs by an O-MCC and a MCC according to an embodiment of the present disclosure;

FIG. 9B is a graph illustrating the result of comparing charge times by an O-MCC and a MCC according to an embodiment of the present disclosure;

FIG. 9C is a graph illustrating the result of comparing capacities by an O-MCC and a MCC according to an embodiment of the present disclosure;

FIG. 10 is a flowchart illustrating a battery charging method according to embodiments of the present disclosure;

FIG. 11A is a graph illustrating the result of comparing battery SOHs by an O-MMC and a MCC to which different constraints are applied according to embodiments of the present disclosure;

FIG. 11B is a graph illustrating the result of comparing charge times by an O-MMC and a MCC to which different constraints are applied according to embodiments of the present disclosure;

FIG. 11C is a graph illustrating the result of comparing total heat generation by an O-MMC and a MCC to which different constraints are applied according to embodiments of the present disclosure;

FIG. 11D is a graph illustrating the result of comparing capacities by an O-MMC and a MCC to which different constraints are applied according to embodiments of the present disclosure; and

FIG. 12 is a graph illustrating performance of a fast charging algorithm according to embodiments of the present disclosure.

### DETAILED DESCRIPTION

Hereinafter, some embodiments of the present disclosure are described in detail with reference to the accompanying drawings. In adding the reference numerals to the components of each drawing, it should be noted that the identical components are designated by the identical numerals even when the components are displayed on different drawings. Further, in describing embodiments of the present disclosure, where it was determined that a detailed description of well-known features or functions would obscure the gist of the present disclosure, the detailed description thereof has been omitted.

In describing components of embodiments of the present disclosure, the terms first, second, A, B, (a), (b), and the like may be used herein. These terms are only used to distinguish one component from another component. These terms do not limit the corresponding components irrespective of the order or priority of the corresponding components. Furthermore, unless otherwise defined, all terms including technical and scientific terms used herein have the same meaning as being generally understood by those having ordinary skill in the art to which the present disclosure pertains. Such terms as those defined in a generally used dictionary should be interpreted as having meanings equivalent to the contextual meanings in the relevant field of art, and should not be interpreted as having ideal or excessively formal meanings unless clearly defined as having such in the present application.

In the present disclosure, when a component, controller, device, element, apparatus, unit or the like of the present disclosure is described as having a purpose or performing an operation, function, or the like, the component, controller, device, element, apparatus, unit or the like should be considered herein as being “configured to” meet that purpose or to perform that operation or function. Each component, controller, device, element, apparatus, unit, or the like may separately embody or be included with one or more processors and a memory, such as a non-transitory computer-readable media, as part of the apparatus.

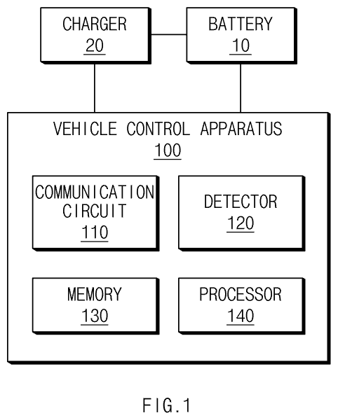

FIG. 1 is a block configuration diagram illustrating a battery charging system according to embodiments of the present disclosure.

The battery charging system may include a battery 10, a charger 20, and a vehicle control apparatus 100.

The battery 10 may store electric energy. The battery 10 may be used in an electronic device, an electric vehicle, a hybrid electric vehicle, an energy storage system (ESS), and/or the like. A lithium-ion battery may be used as the battery 10.

Although not illustrated in the drawing, the lithium-ion battery may include or be composed of a positive electrode (or a cathode), a negative electrode (or an anode), an electrolyte, and a separator. The positive electrode is a space where lithium is inserted in the lithium-ion battery. A capacity and a voltage of the lithium-ion battery may be determined according to an active material of the positive electrode. The positive electrode may be made of lithium metal oxide. The negative electrode may play a role in storing and emitting lithium ions from the positive electrode such that a current flows via an external circuit. Graphite may be used as an active material of the negative electrode. The amount of ions capable of being stored as the structure of graphite changes as the process in which the negative electrode stores and emits lithium ions is repeated is reduced. Due to this, a battery state of health (SOH) is reduced. The electrolyte is a medium that helps lithium ions to move between the positive electrode and the negative electrode. The electrolyte may include or be composed of an organic solvent in which a lithium salt is dissolved. The separator plays a role in physically blocking contact between the positive electrode and the negative electrode. The separator may electrically be an insulator, but may selectively have permeability such that lithium ions are able to pass. Polythene (PE), polypropylene (PP), and/or the like may be used as the separator.

The charger 20 may adjust and supply electric energy (or a voltage and/or a current) supplied from a power supply source to the battery 10 to suit a characteristic of the battery 10, thus charging the battery 10. An alternating current (AC) voltage or a direct current (DC) voltage may be used as the power supply source.

Although not illustrated in the drawing, the charger 20 may include a rectifier, a converter, a charge controller, a protection circuit, an interface, and/or the like. The rectifier may rectify power supplied from the power supply source. The rectifier may convert an AC voltage into a DC voltage. The converter may convert the DC voltage rectified by the rectifier into a voltage and/or current based on the characteristic of the battery 10. The converter may include at least one of a buck converter, a boost converter, a buck-boost converter, or any combination thereof. The charge controller may monitor a state of charge (SOC), a temperature, a voltage, and/or the like of the battery 10. The charge controller may measure a voltage, a current, a temperature, and/or the like of the battery 10 using (or based on signals obtained from) a voltage sensor, a current sensor, and/or a temperature sensor installed in the battery 10. The charge controller may execute a charging algorithm stored in a memory. The protection circuit may stop charging upon overcurrent, overpotential, and/or abnormality in temperature to prevent battery damage or fire. The interface may be an output terminal connected with a terminal of the battery 10. The interface may output the voltage and/or current converted by the converter to the battery 10. The interface may enable, and/or assist in performing, communication between the charger 20 and an external device (e.g., the vehicle control apparatus 100, a battery management system (BMS), or the like).

The vehicle control apparatus 100 may be an electronic control unit (ECU) mounted into the vehicle. The vehicle control apparatus 100 may include a communication circuit 110, a detector 120, a memory 130, a processor 140, and the like.

The communication circuit 110 may enable, and/or assist in executing, wired communication and/or wireless communication between the vehicle control apparatus 100 and an external device (e.g., the battery 10, the charger 20, the BMS, a server, and/or the like). The communication circuit 110 may include a wireless communication circuit (e.g., a short range wireless communication circuit, a Bluetooth communication circuit, a mobile communication circuit, and/or the like) and/or a wired communication circuit (e.g., a controller area network (CAN) communication circuit, a local area network (LAN) communication circuit, a power line communication circuit, and/or the like).

The detector 120 may detect state information of the battery 10 (or cell state information). The detector 120 may obtain state information of the battery 10 using (or based on one or more signals obtained from) one or more sensors, such as the voltage sensor, the current sensor, and/or the temperature sensor, installed in the battery 10. The state information of the battery 10 may include at least one of a voltage, a current, a temperature, a heat generation rate (HGR), a state of charge (SOC), a state of health (SOH), or any combination thereof.

In another embodiment, the detector 120 may obtain state information of the battery 10 via the communication circuit 110. The detector 120 may obtain state information of the battery 10 from the BMS via the communication circuit 110.

The memory 130 may store at least one of an electrochemical-thermal-life model, an electrochemical model, a thermal model, a degradation model (or a life model), an optimization algorithm, a fast charging algorithm, or any combination thereof. The optimization algorithm may be a nonlinear model predictive control (NMPC) algorithm. The fast charging algorithm may include a multi-stage constant current (MCC) charging algorithm, an optimized MCC (O-MCC) charging algorithm, and/or the like.

Furthermore, the memory 130 may store a variable charging map. The variable charging map may be a lookup table (LUT) in which an optimal charge current corresponding to the voltage and the SOH of the battery 10 is defined.

The memory 130 may be a non-transitory storage medium that stores instructions executable by the processor 140. The memory 130 may include at least one of a flash memory, a hard disk, a solid state disk (SSD), a secure digital (SD) card, a random access memory (RAM), a static RAM (SRAM), a read only memory (ROM), a programmable ROM (PROM), an electrically erasable and programmable ROM (EEPROM), an erasable and programmable ROM (EPROM), an embedded multimedia card (eMMC), or any combination thereof.

The processor 140 may control the overall operation of the vehicle control apparatus 100. The processor 140 may include at least one of an application specific integrated circuit (ASIC), a digital signal processor (DSP), a programmable logic device (PLD), a field programmable gate array (FPGA), a central processing unit (CPU), a microcontroller, a microprocessor, or any combination thereof.

The processor 140 may optimize the fast charging algorithm (or a charging algorithm or a charging protocol). The processor 140 may perform optimization of the charging algorithm based on (or using) the NMPC algorithm based on a reduced order electrochemical-thermal-life model including electrochemical degradation mechanisms, such as a side reaction and a lithium plating reaction.

The optimized fast charging algorithm may calculate magnitudes of the charging currents and transition points of the MCC. The optimized fast charging algorithm may be designed to aim at minimizing lithium plating formation and shortening a charge time. The minimization of the lithium plating formation may be achieved by forcing lithium plating overpotential to be maintained within an overpotential upper limit and an overpotential lower limit throughout the overall battery SOH.

The processor 140 may generate the optimized fast charging algorithm in the form of a lookup table (or a variable charging map). The processor 140 may store the generated lookup table in the memory 130. Furthermore, the processor 140 may apply the generated lookup table in the BMS.

Furthermore, the processor 140 may generate a charging map suitable for needs of a user (or a developer). The processor 140 may generate the charging map for each charge time, temperature, and/or lithium plating constraint. In other words, the processor 140 may generate the charging map in a situation in which a composite constraint is considered.

The processor 140 may measure (or obtain) a voltage and a SOH of the battery 10 using (or based on one or more signals obtained from) one or more sensors installed in the battery 10. The processor 140 may determine an optimal charge current corresponding to the measured voltage and SOH with reference to (or based on, or using) the variable charging map. The processor 140 may deliver the determined optimal charge current to the charger 20 via the communication circuit 110. The charger 20 may control a current (or a charge current) supplied to the battery 10 based on the determined optimal charge current.

Hereinafter, a process of optimizing the fast charging algorithm, according to an embodiment, is described in more detail.

When optimization is initiated, the processor 140 may proceed with initialization. The processor 140 may set time t to “1” and may set an initial SOC SOC(1) of the battery 10 to a SOC SOCₛₜₐᵣₜ of the battery 10 at a charging start time point.

The processor 140 may determine whether a current Soc SOC(t) of the battery 10 is less than a fast charging upper limit Soc SOC_{end}. The fast charging upper limit SOC may be predefined for each vehicle type by a system designer. When it is determined that the current SOC of the battery 10 is greater than or equal to the fast charging upper limit SOC, the processor 140 may end fast charging. In other words, the fast charging upper limit SOC may be criteria for determining whether charging is stopped (or ended).

When it is determined that the current SOC of the battery 10 is less than the fast charging upper limit SOC, the processor 140 may determine whether a current voltage V(t) of the battery 10 is greater than or equal to a fast charging upper limit voltage V_{end}. The fast charging upper limit voltage may be predefined for each vehicle type by the system designer. The current voltage V(t) corresponds to the computation result of the electrochemical model.

When it is determined that the current voltage of the battery 10 is greater than or equal to the fast charging upper limit voltage, the processor 140 may reduce a charge current (C-rate) by a predetermined factor (e.g., by half) or at a predefined rate k. This may be represented as Equation 1 below.

$$I ( t ) = I ( t - 1 ) / k \qquad [ Equation 1 ]$$

In Equation 1, I(t) is the current in time (t seconds).

When it is determined that the current voltage of the battery 10 is not greater than or equal to the fast charging upper limit voltage, the processor 140 may determine whether at least one of the following NMPC start conditions (or optimization algorithm start conditions) is satisfied.

### NMPC Start Conditions

1) When the time is 1 second (t=1)
2) When the constant current (CC) application time tcc is greater than the CC application end time tcc_{end} and the lithium plating overpotential η_{LiP} is less than the allowable lithium plating overpotential η_{allow} (tcc>tcc_{end} and η_{LiP}<η_{allow})

Herein, the lithium plating overpotential η_{LiP} refers to a voltage (or a potential) for starting to cause lithium plating on a negative electrode surface while charting a lithium-ion battery. The lithium plating overpotential nip may be the computation result of the electrochemical model. The CC application end time tcc_{end} may be predefined for each vehicle type by the system designer.

When it is determined that the at least one of the NMPC start conditions is satisfied, the processor 140 may perform NMPC. The processor 140 may execute the NMPC algorithm based on the electrochemical-thermal-life model.

An objective function of the NMPC may be represented as Equation 2 below.

$${I}_{opt} ( t ) = {arg min}_{I ∈ [ - 5 C , - C / 3 ]} ( {\int }_{t}^{t + {N}_{h}} I dt ) \qquad [ Equation 2 ]$$

Herein, Nₕ is a predetermined time (e.g., 3 seconds).

A boundary condition (or a constraint) may be set to “η_{LiP}>η_{lb}”. Herein, η_{lb} is a lithium plating (LiP) overpotential lower limit.

After performing the NMPC, the processor 140 may initialize the CC application time tcc. In other words, the processor 140 may set “tcc=1”.

When it is determined that the NMPC start condition is not satisfied, the processor 140 may maintain a previous C-rate and may continue constant current charging. In other words, the processor 140 may determine a charge current I(t) in t seconds as a previous charge current I(t−1). The charge current I(t) may be the computation result of the electrochemical model.

Next, the processor 140 may accumulate a constant current duration Δt to the constant current application time to update the constant current application time (tcc=tcc+Δt).

The processor 140 may reflect a predetermined charge current to execute the electrochemical-thermal-life model. In other words, the processor 140 may optimize the electrochemical-thermal-life model.

The processor 140 may generate a lookup table (or a variable charging map) for each voltage and SOH of the battery 10 based on (or using) the optimized electrochemical-thermal-life model. In other words, the processor 140 may generate an O-MCC algorithm (or an optimized fast charging algorithm) based on (or using) the optimized electrochemical-thermal-life model. The O-MCC algorithm may include magnitudes of the charge currents of the MCC and transition points of the MCC.

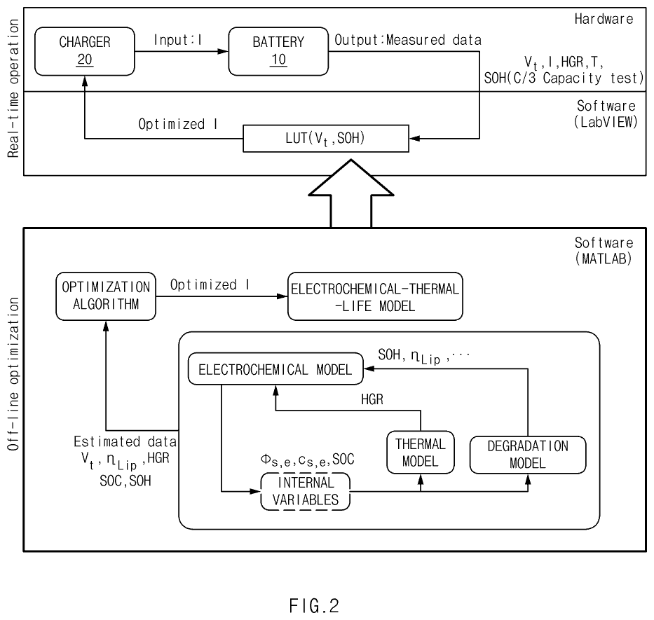

FIG. 2 is a block diagram schematically illustrating a fast charging scheme associated with embodiments of the present disclosure.

A charger 20 may monitor a voltage Vₜ and a SOH of the battery 10 using (or based on one or more signals obtained from) one or more sensors installed in a battery 10. The charger 20 may determine an optimal charge current Optimized I corresponding to the monitored voltage and SOH of the battery 10 with reference to (or based, or using) a variable charging map LUT previously stored in a memory 130 of a vehicle control apparatus 100 or a BMS. The variable charging map LUT is a lookup table in which an optimal charge current is defined for each voltage and SOH of the battery 10. The charger 20 may control a charge current I supplied to the battery 10 based on the determined optimal charge current.

According to another embodiment, the charger 20 may receive an optimal charge current corresponding to a voltage and a SOH of the battery 10 from the vehicle control apparatus 100. The charger 20 may transmit the monitored voltage and SOH of the battery 10 to the vehicle control apparatus 100. The vehicle control apparatus 100 may determine an optimal charge current corresponding to the received monitored voltage and SOH of the battery 10 with reference to the previously stored variable charging map LUT. The vehicle control apparatus 100 may transmit the determined optimal charge current to the charger 20. The charger 20 may control a charge current supplied to the battery 10 based on the optimal charge current received from the vehicle control apparatus 100.

According to another embodiment, the vehicle control apparatus 100 may monitor a voltage and a SOH of the battery 10 using (or based on one or more signals obtained from) the one or more sensors installed in the battery 10. The vehicle control apparatus 100 may determine an optimal charge current corresponding to the monitored voltage and SOH of the battery 10 with reference to the previously stored variable charging map LUT. The vehicle control apparatus 100 may transmit the determined optimal charge current to the charger 20. The charger 20 may control the charge current supplied to the battery 10 based on the optimal charge current transmitted from the vehicle control apparatus 100.

The vehicle control apparatus 100 may optimize a fast charging algorithm. The vehicle control apparatus 100 may generate a variable charging map LUT based on (or using) the optimized electrochemical-thermal-life model. The electrochemical-thermal-life model is a battery model in which a thermal model, a degradation model, and an electrochemical model are combined with one another. Herein, the degradation model may also be referred to as a life model.

The electrochemical model may receive data of at least one of a current, a voltage, or a temperature (or an ambient temperature), or any combination thereof as an input. The electrochemical model may perform computation based on (or using) the received data and may output at least one of a voltage, a current, a temperature, a heat generation rate (HGR), a SOC, a SOH, or internal variables, or any combination thereof as the result of the computation. The internal variables may include a model parameter, such as ion concentration cₛ in electrode, ion concentration cₑ in electrolyte, potential Øₛ in the electrode, potential Øₑ in the electrolyte, or a reaction rate.

The thermal model may use the internal variables as model parameters to perform computation and may output a heat generation rate as the result of the computation. The degradation model may perform computation based on (or using) the internal variables and may output a SOH and lithium plating overpotential as the result of the computation.

The electrochemical model may estimate a voltage, lithium plating overpotential, a heat generation rate, a SOC, and a SOH based on the heat generation rate output from the thermal model and the SOH and the lithium plating overpotential output from the degradation model. The electrochemical model may output the estimated pieces of data to an optimization algorithm. The optimization algorithm may optimize a current (or a charge current) based on the pieces of data estimated by the electrochemical model. The optimization algorithm may apply (or reflect) the optimized current Optimized I to (or in) the electrochemical-thermal-life model.

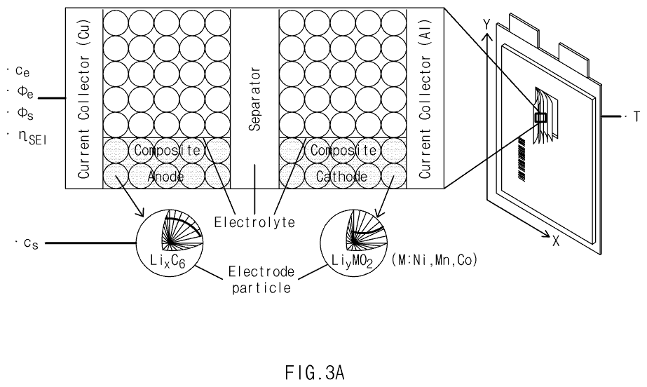

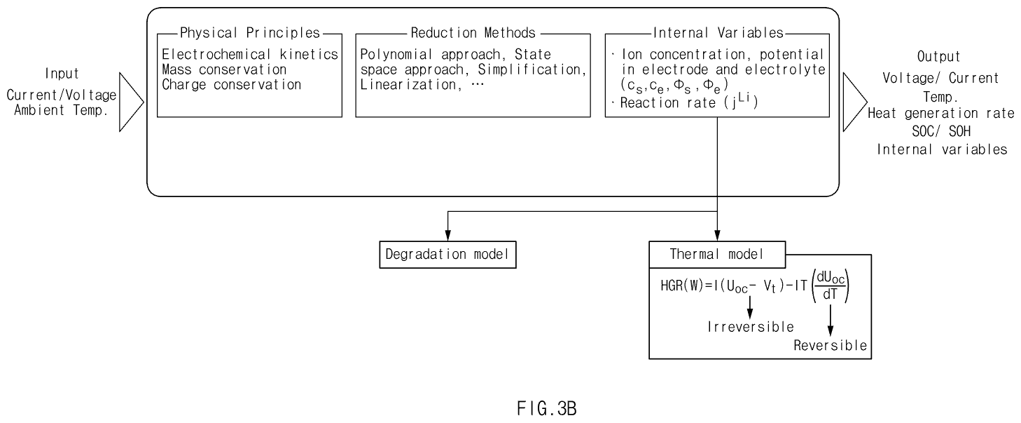

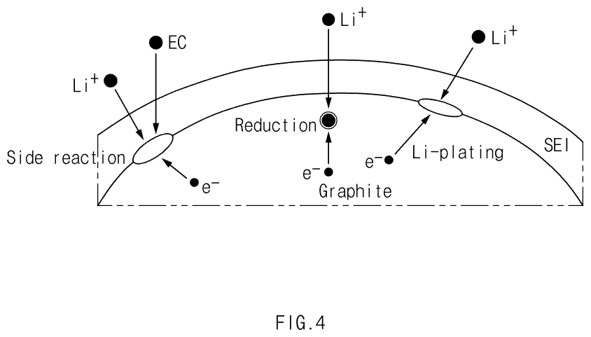

FIG. 3A is a schematic diagram illustrating a microcell associated with embodiments of the present disclosure. FIG. 3B is a drawing illustrating a structure of an electrochemical-thermal-life model according to embodiments of the present disclosure. FIG. 4 is a drawing illustrating electrochemical degradation mechanisms according to embodiments of the present disclosure.

Referring to FIG. 3A, the microcell may include or be composed of a composite anode mixed with an electrolyte, a separator, and a composite cathode mixed with the electrolyte. The composite anode may be composed of graphite LiₓC₆ into which lithium is inserted. When the cell is discharged, lithium ions may be separated from the composite anode to move to a cathode via the electrolyte. The composite cathode may be composed of lithium metal oxide (LiₓMO₂, M: Ni, Mn, CO). When the cell is charged, lithium ions may be stored by moving to the composite cathode via the electrolyte. The separator may pass the lithium ions while physically separating the anode and the cathode. The electrolyte may allow the lithium ions to move between the anode and the cathode. Current collectors provided in the anode and the cathode may play a role as passages for moving electrons generated in a process in which a cell is charged or discharged.

Referring to FIG. 3B, an electrochemical-thermal-life model is an electrochemical model based on a reduced order model in which a thermal model and a degradation model are combined with each other.

When the internal variables are received, the thermal model may calculate and output a heat generation rate based on the internal variables. The heat generation rate (HGR) be represented as Equation 3 below.

$$HGR ( W ) = I ( {U}_{oc} - {V}_{t} ) - IT ( \frac{{dU}_{oc}}{dT} ) \qquad [ Equation 3 ]$$

In Equation 3, I is the current, Vₜ is the voltage in time (t seconds), T is the temperature, U_{oc} is the open circuit voltage, and dU_{oc}/dT is the entropic coefficient. A first term may indicate an irreversible reaction and a second term may indicate a reversible reaction.

The degradation model may receive the internal variables and may calculate and output a SOH and lithium plating overpotential based on (or using) the internal variables. Referring to FIG. 4, electrochemical degradation, such as a side reaction and lithium plating (Li-plating), may occur during battery charging. The degradation model may predict degradation and a SOH of a battery 10 with regard to the electrochemical degradation which occurs during the battery charging. At this time, the degradation model may consider electrochemical degradation which occurs under the following assumption.

### Assumption:

Degradation occurs in only the anode.
A side reaction is an irreversible reaction.
Lithium plating is a semi-reversible reaction.
Mechanical degradation, gas generation, over-charging, and over-discharging are not considered.

The degradation model may calculate a reaction rate and overpotential according to electrochemical degradation based on (or using) formulae in Table 1 below.

TABLE 1

| | |
|---|---|
| | Main reaction |
| Reaction rate [A/cm³] | ${j}^{Li} = {a}_{s} {i}_{0} ( exp ( \frac{{α}_{ox} F}{RT} η ) - exp ( - \frac{{α}_{rd} F}{RT} η ) )$ |
| Overpotential | $η = {ϕ}_{s} - {ϕ}_{e} - {U}_{eq} - \frac{{R}_{SEI}}{{a}_{s}} {j}_{total}^{Li}$ |
| | Side reaction |
| Reaction rate [A/cm³] | ${j}_{total}^{Li} = - {a}_{s} {i}_{0 , side} exp ( \frac{{α}_{rd , side} {n}_{side} F}{RT} {η}_{side} )$ |
| Overpotential | ${η}_{side} = {ϕ}_{s} - {ϕ}_{e} - {U}_{eq , side} - \frac{{R}_{SEI}}{{a}_{s}} {j}_{total}^{Li}$ |
| | Lithium plating/stripping |
| Reaction rate [A/cm³] | ${j}_{total}^{Li} = - {a}_{s} {i}_{0 , Li} exp ( - \frac{{α}_{rd , Li} F}{RT} {η}_{LiP} )$ |
| Overpotential | ${η}_{LiP} = {ϕ}_{s} - {ϕ}_{e} - {U}_{eq , LiP} - \frac{{R}_{SEI}}{{a}_{s}} {j}_{total}^{Li}$ |
| | η_{LiP} = min(η_{LiP}, 0) |
| Total reaction rate | ${j}_{total}^{Li} = {j}^{Li} + {j}_{side}^{Li} + {j}_{LiP}^{Li}$ |

In Table 1, aₛ is the specific reaction area and R_{SEI} is the resistance of the solid electrolyte interphase (SEI). αₒₓ, α_{rd}, α_{rd,side} α_{rd,Li}, and α_{ox,Li} are the constants, F is the Faraday constant, R is the resistance, and T is the temperature. U_{eq} is the equilibrium potential of the main reaction, U_{eq,side} is the equilibrium potential of the side reaction, and U_{eq,Li} is the equilibrium potential of the lithium plating and stripping. n_{side} is the ion number which participates in the side reaction. i₀ is the exchange current density, which may be represented as Equation 4 below.

$${i}_{0} = {k ( {c}_{e} )}^{{a}_{ox}} {( {c}_{s , max} - {c}_{s} )}^{{α}_{ox}} {c}_{s}^{{α}_{rd}} \qquad [ Equation 4 ]$$

In Equation 4, k is the kinetic rate constant.

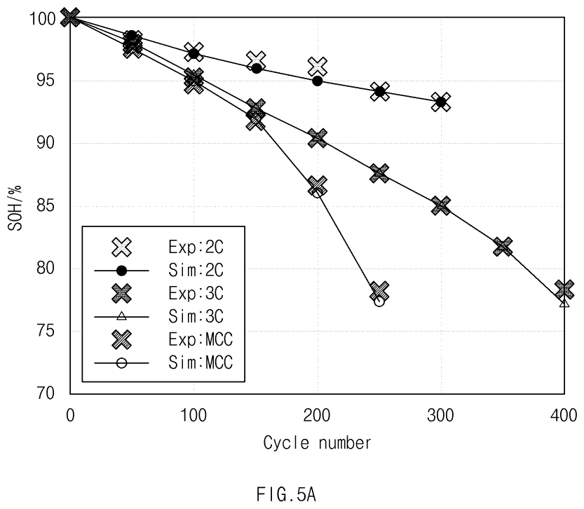

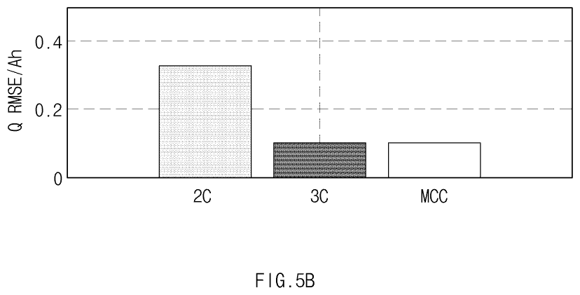

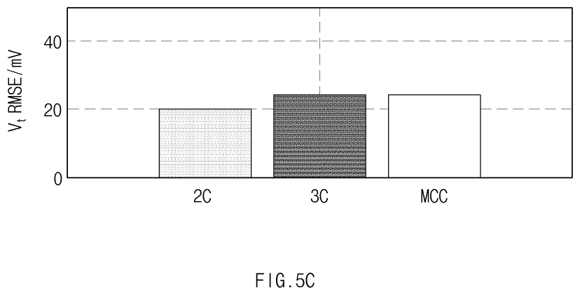

FIG. 5A is a graph illustrating a battery state of health (SOH) of the result of verifying a degradation model associated with embodiments of the present disclosure. FIG. 5B is a graph illustrating a capacity root mean square error (RMSE) of the result of verifying a degradation model associated with embodiments of the present disclosure. FIG. 5C is a graph illustrating a voltage RMSE of the result of verifying a degradation model associated with embodiments of the present disclosure.

To verify a degradation model (or a durability prediction model), 2C CC, 3C CC, and MCC charging schemes and a 1C CC discharging scheme are set as testing conditions in an environment of 25° C. to proceed with simulation and experiment.

Referring to FIG. 5A, it may be checked that a SOH derived via the simulation is similar to a SOH obtained via the experiment.

Referring to FIG. 5B, an error between a battery capacity predicted via the simulation and a real battery capacity obtained via the experiment, that is, a capacity prediction error (or a capacity absolute error) is represented as a level of about 2%. In other words, it is checked that it is possible to accurately predict capacity reduction of a degradation model.

Referring to FIG. 5C, an error between a battery voltage predicted via the simulation and a real battery voltage obtained via the experiment, that is, a capacity prediction error Vₜ (or a root mean square error (RMSE)) is represented as a level less than 35 mV.

It is checked that battery durability prediction accuracy of the degradation model is good, via the verification of the degradation model.

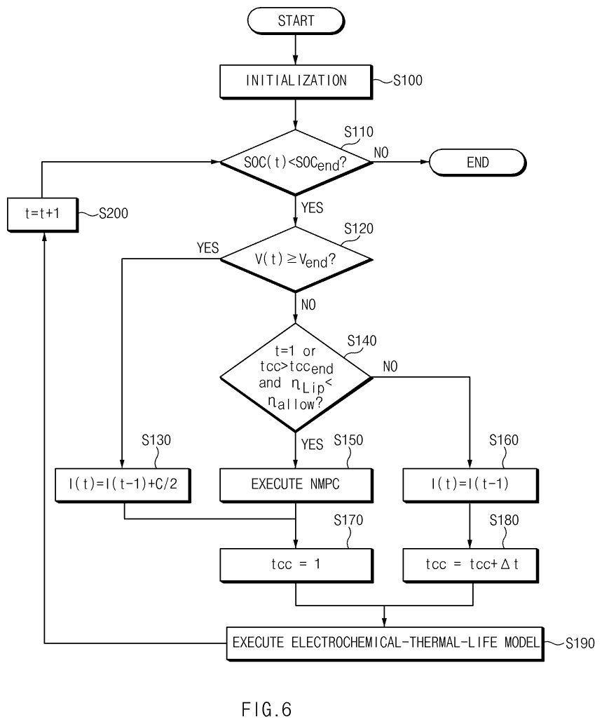

FIG. 6 is a flowchart illustrating a method for optimizing a fast charging algorithm according to embodiments of the present disclosure.

When optimization is initiated, in an operation S100, a processor 140 of a vehicle control apparatus 100 may proceed with initialization. The processor 140 may set time t to “1” and may set an initial SOC SOC(1) of the battery 10 to a SOC SOCₛₜₐᵣₜ of the battery 10 at a charging start time point.

In an operation S110, the processor 140 may determine whether a current SOC SOC(t) of the battery 10 is less than a fast charging upper limit SOC SOC_{end}. The fast charging upper limit SOC may be predefined for each vehicle type by a system designer. When it is determined that the current SOC of the battery 10 is greater than or equal to the fast charging upper limit SOC, the processor 140 may end fast charging.

When it is determined that the current SOC of the battery 10 is less than the fast charging upper limit SOC, in an operation S120, the processor 140 may determine whether a current voltage V(t) of the battery 10 is greater than or equal to a fast charging upper limit voltage V_{end}. The fast charging upper limit voltage V_{end} may be predefined for each vehicle type by the system designer. The current voltage V(t) corresponds to the computation result of an electrochemical model.

When it is determined that the current voltage of the battery 10 is greater than or equal to the fast charging upper limit voltage, the processor 140 may reduce a charge rate (C-rate) by a predetermined factor (e.g., by half (C/2)) or at a predetermined rate.

When it is determined that the current voltage of the battery 10 is not greater than or equal to the fast charging upper limit voltage in the operation S120, in an operation S140, the processor 140 may determine whether an optimization algorithm start condition is satisfied. A nonlinear model predictive control (NMPC) algorithm may be used as the optimization algorithm.

### Optimization Algorithm Start Condition:

1) When the time is 1 second (t=1)
2) When the constant current (CC) application time tcc is greater than the CC application end time tcc_{end} and the lithium plating overpotential η_{LiP} is less than the allowable lithium plating overpotential η_{allow} (tcc>tCC_{end} and η_{LiP}<η_{allow})

Herein, the lithium plating overpotential η_{LiP} refers to a voltage for starting to cause lithium plating on a negative electrode surface while charting a lithium-ion battery. The lithium plating overpotential nip may be the computation result of the electrochemical model. The CC application end time tcc_{end} may be predefined for each vehicle type by the system designer.

When it is determined that at least one of the optimization algorithm start conditions is satisfied, in an operation S150, the processor 140 may execute the optimization algorithm. In other words, the processor 140 may execute the optimization algorithm based on an electrochemical-thermal-life model.

When it is determined that the optimization algorithm start condition is not satisfied in the operation S140, in an operation S160, the processor 140 may maintain a previous C-rate and may continue constant current charging. In other words, the processor 140 may determine a charge current I(t) in t seconds as a previous charge current I(t−1). The charge current I(t) may be the computation result of the electrochemical model.

In an operation S170, the processor 140 may initialize the CC application time tcc. In other words, the processor 140 may set “tcc=1”.

After the operation S160, in an operation S180, the processor 140 may accumulate a CC duration Δt to the CC application time tcc to update the CC application time (tcc=tcc+Δt).

In an operation S190, the processor 140 may execute the electrochemical-thermal-life model. The processor 140 may perform optimization of the electrochemical-thermal-life model. The processor 140 may generate a variable charging map based on (or using) the optimized electrochemical-thermal-life model.

In an operation S200, the processor 140 may perform computation of adding 1 second to time t and may return to the operation S110. In other words, the processor 140 may increase time t by “1”.

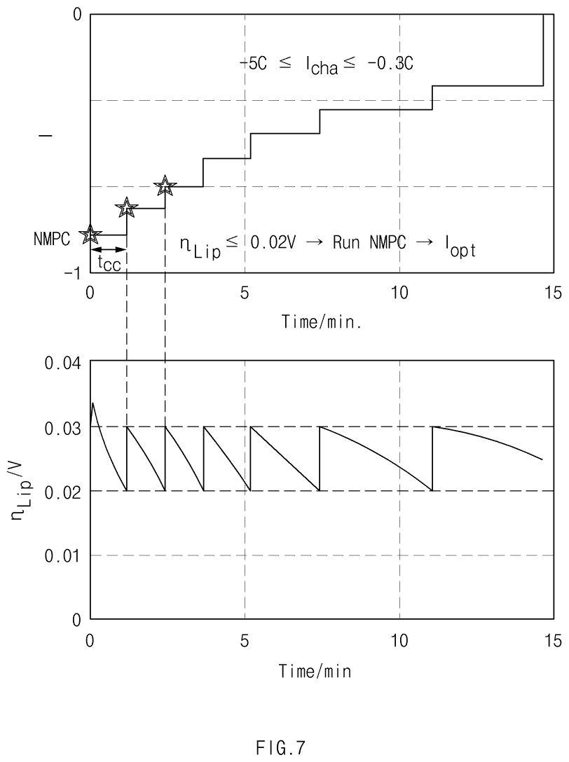

FIG. 7 illustrates the result of simulating an optimized multi-stage constant current (O-MCC) in an initial battery SOH interval according to embodiments of the present disclosure.

A MCC may be optimized via a nonlinear model predictive control algorithm based on a reduced electrochemical-thermal-life model including electrochemical degradation mechanisms, such as a side reaction and a lithium plating reaction.

Referring to FIG. 7, when lithium plating overpotential η_{LiP} is less than or equal to 0.02 V, a vehicle control apparatus 100 may execute NMPC to optimize a charge current. The vehicle control apparatus 100 may search for a charge current (C-rate) I_{cha} for the case in which the lithium plating overpotential η_{LiP} is greater than 0.03 V based on (or using) the NMPC.

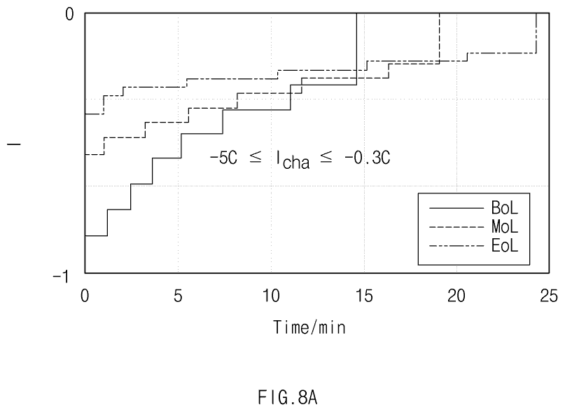

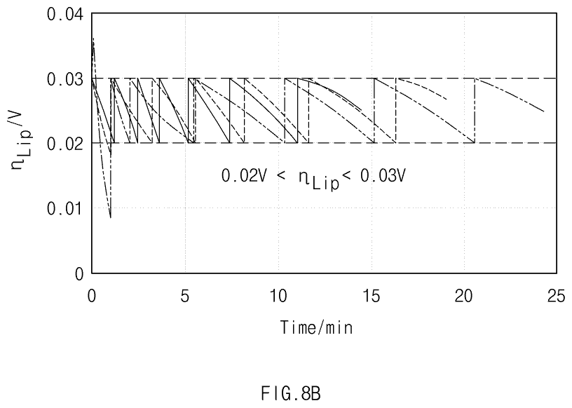

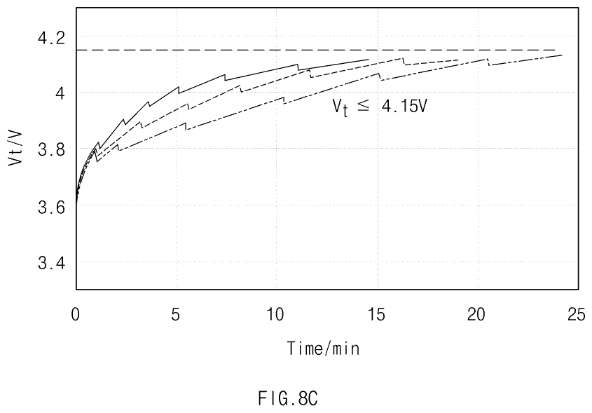

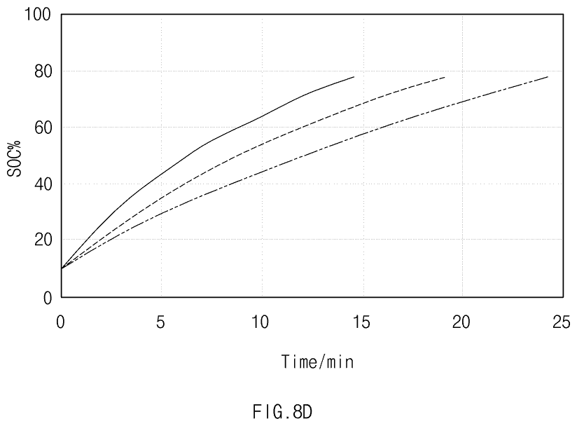

FIG. 8A illustrates a current graph of the result of simulating an O-MCC according to embodiments of the present disclosure. FIG. 8B illustrates an overpotential graph of the result of simulating an O-MCC according to embodiments of the present disclosure. FIG. 8C illustrates a voltage graph of the result of simulating an O-MCC according to embodiments of the present disclosure. FIG. 8D illustrates a SOC graph of the result of simulating an O-MCC according to embodiments of the present disclosure.

The charge rate (C-rate) is reduced in an aged cell and lithium plating does not occur up to the end of life (EoL).

A constraint is kept consistent in the entire battery life interval (beginning of life (BoL), middle of life (MoL), and EoL) (refer to FIGS. 8A to 8D). However, it is checked that a system temporarily deviates from a lithium plating overpotential constraint due to a CC constraint in an interval of 0-1 minutes.

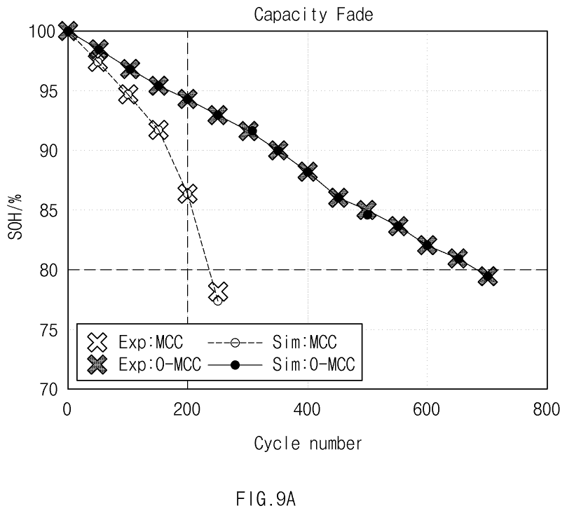

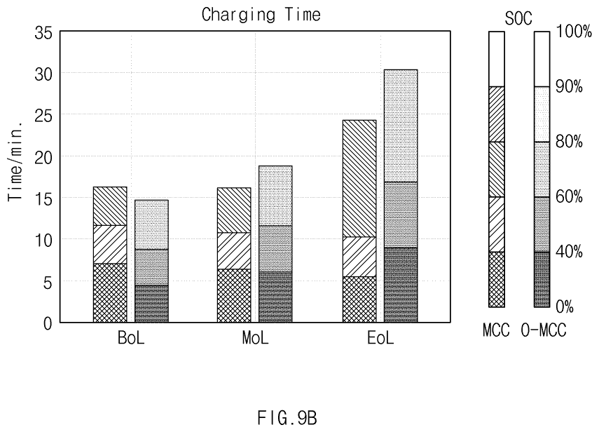

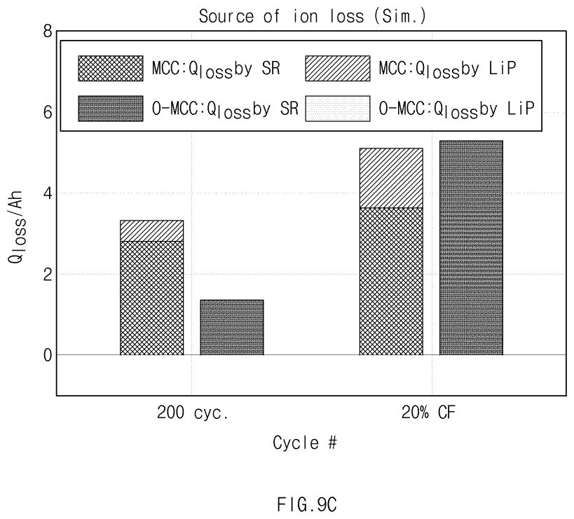

FIG. 9A is a graph illustrating the result of comparing battery SOHs by an O-MCC and a MCC according to an embodiment of the present disclosure. FIG. 9B is a graph illustrating the result of comparing charge times by an O-MCC and a MCC according to an embodiment of the present disclosure. FIG. 9C is a graph illustrating the result of comparing capacities by an O-MCC and a MCC according to an embodiment of the present disclosure.

A charging profile may optimize C-rates and voltage criteria based on (or using) an NMPC algorithm and may suppress lithium plating up to EoL based on (or using) a variable charging map based on a voltage and a SOH.

Referring to FIG. 9A, an O-MCC may extend a SOH of the battery 10 as compared to a MCC.

Referring to FIG. 9B, the O-MCC may shorten a charge time of the battery 10 by 11.7% as compared to the MCC.

Referring to FIG. 9C, the O-MCC may reduce capacity fade (CF) as compared to the MCC. Particularly, it may be seen that the O-MCC reduces the capacity fade by 59.4% in cycle 200 as compared to the MCC.

As such, the O-MCC may suppress lithium plating in the entire battery life interval to greatly improve battery safety.

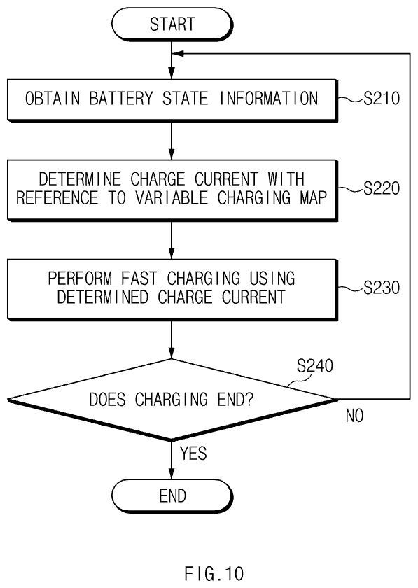

FIG. 10 is a flowchart illustrating a battery charging method according to embodiments of the present disclosure.

In an operation S210, a charger 20 may obtain battery state information. The charger 20 may obtain state information of a battery 10 using (or based on one or more signals obtained from) one or more sensors installed in the battery 10. The state information of the battery 10 may include a voltage, a SOH, and the like.

In an operation S220, the charger 20 may determine a charge current with reference to a previously stored variable charging map. The charger 20 may determine an optimal charge current corresponding to the state information of the battery 10, that is, the voltage and the SOH, which is obtained with reference to the previously stored variable charging map.

In an operation S230, the charger 20 may perform fast charging using the determined charge current. The charger 20 may control a charge current supplied to the battery 10 based on the determined optimal charge current.

In an operation S240, the charger 20 may determine whether the charging ends. When the charging end is determined, the charger 20 may end battery charging. When the charging end is not determined, the charger 20 may return to the operation S210.

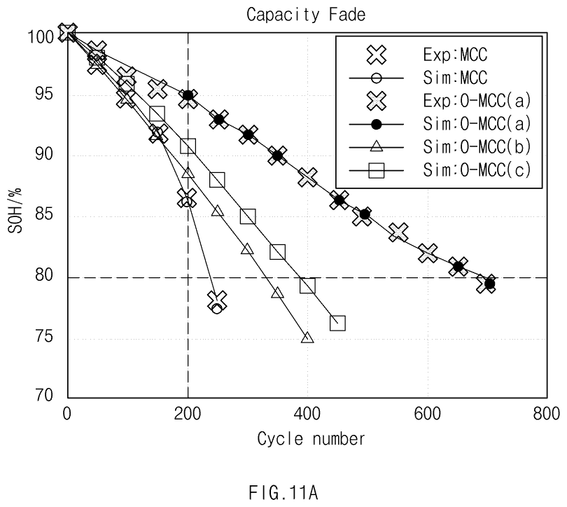

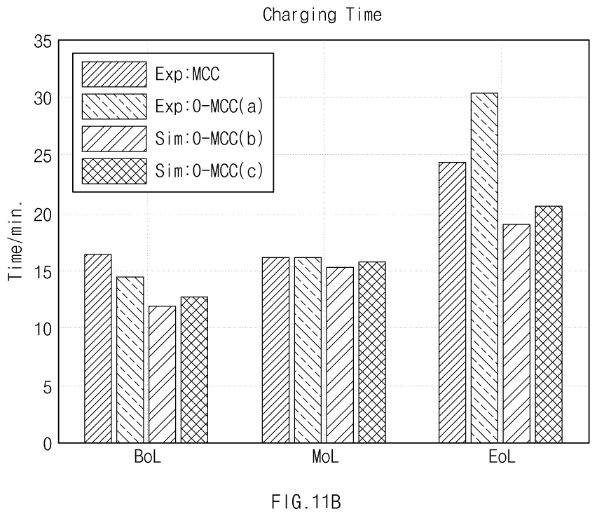

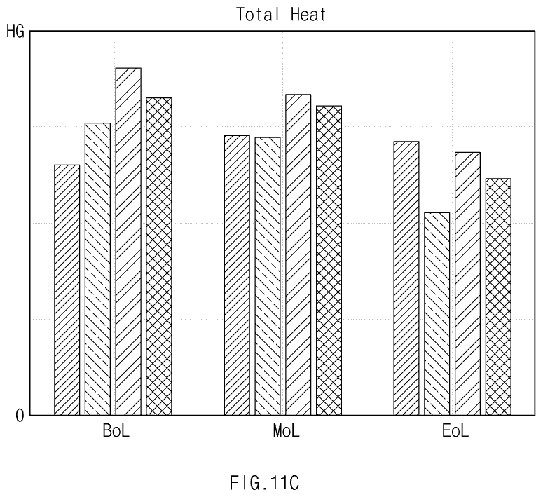

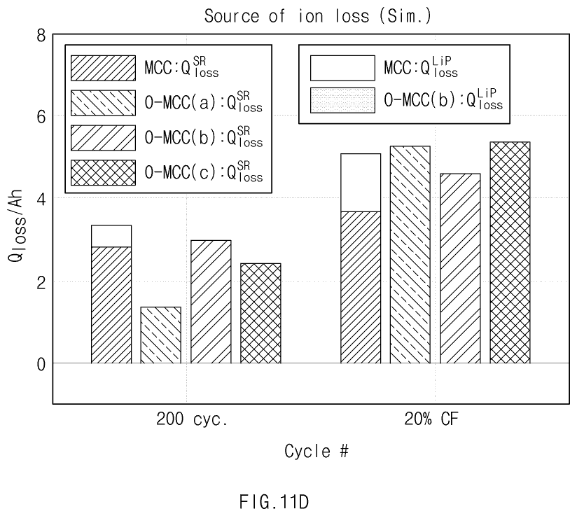

FIG. 11A is a graph illustrating the result of comparing battery SOHs by an O-MMC and a MCC to which different constraints are applied according to embodiments of the present disclosure. FIG. 11B is a graph illustrating the result of comparing charge times by an O-MMC and a MCC to which different constraints are applied according to embodiments of the present disclosure. FIG. 11C is a graph illustrating the result of comparing total heat generation by an O-MMC and a MCC to which different constraints are applied according to embodiments of the present disclosure. FIG. 11D is a graph illustrating the result of comparing capacities by an O-MMC and a MCC to which different constraints are applied according to embodiments of the present disclosure.

The MCC may simultaneously consider various factors, such as a charge time, degradation, and heat generation. The O-MCC may generate a charging profile depending on user requirements.

For example, the O-MCC may generate a charging profile optimized according to the following constraints.

### O-MCC Constraints:

O-MCC(a): 0.02 V≤η_{LiP}≤0.03 V
O-MCC(b): 0 V≤η_{LiP}≤0.01 V
O-MCC(c): 0 V≤η_{LiP}≤0.01 V and HGR<30 W

Referring to FIG. 11A, O-MCC(a), O-MCC(b), and O-MCC(c) extend a SOH of the battery 10 as compared to the MCC.

Referring to FIG. 11B, in the beginning of life (BoL), O-MCC(a), O-MCC(b), and O-MCC(c) reduce a charge time of the battery 10 as compared to the MCC.

Referring to FIG. 11C, in the beginning of life (BOL) and the middle of life (MOL) of the battery 10, O-MCC(a), O-MCC(b), and O-MCC(c) generate more heat than the MCC. In the end of life (EoL) of the battery 10, O-MCC(a), O-MCC(b), and O-MCC(c) reduce heat generation as compared to the MCC.

Referring to FIG. 11D, O-MCC(a), O-MCC(b), and O-MCC(c) may improve durability of the battery 10 as compared to the MCC.

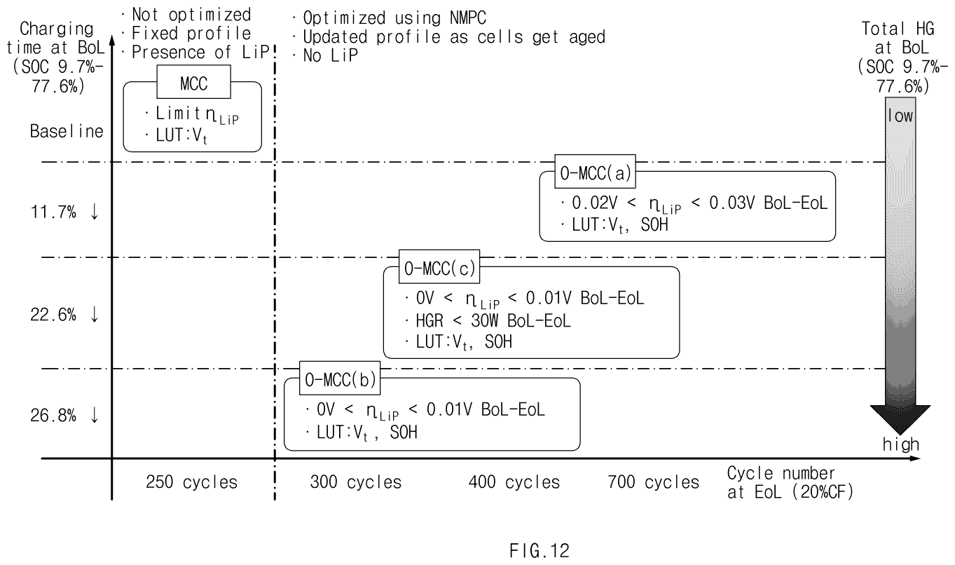

FIG. 12 is a graph illustrating performance of a fast charging algorithm according to embodiments of the present disclosure.

A MCC(a) algorithm reduces a charge time by 11.7% as compared to a MCC algorithm. An O-MCC(c) algorithm reduces a charge time by 22.6% as compared to the MCC algorithm. An O-MCC(b) algorithm reduces a charge time as compared to the MCC algorithm.

The MCC(a) algorithm, the O-MCC(b) algorithm, and the O-MCC(c) algorithm increases a battery SOH as compared to the MCC algorithm.

The MCC(a) algorithm, the O-MCC(b) algorithm, and the O-MCC(c) algorithm increases a heat generation rate as compared to the MCC algorithm.

The algorithm may shorten a charge time, reduce capacity fade to effectively suppress lithium plating throughout the overall battery SOH from the BOL to the EoL, thus greatly improving battery safety.

Embodiments of the present disclosure may optimize a charging condition suitable for a current cell state of a battery, thus suppressing lithium plating and heat generation in the entire battery life interval.

Furthermore, embodiments of the present disclosure may optimize a charge current and a cut-off voltage, thus minimizing lithium plating, suppressing heat generation, and shortening a charge time.

Furthermore, embodiments of the present disclosure may optimize a fast charging scheme based on (or using) a nonlinear model predictive control (NMPC) algorithm based on an electrochemical-thermal-life model, thus suppressing degradation and over-heat generation to improve durability and safety of the battery.

Furthermore, embodiments of the present disclosure may generate a charging map for each charge time, temperature, and lithium plating constraint based on needs of a user (or a developer).

Hereinabove, although the present disclosure has been described with reference to example embodiments and the accompanying drawings, the present disclosure is not limited thereto. Rather, the present disclosure may be variously modified and altered by those having ordinary skill in the art to which the present disclosure pertains without departing from the spirit and scope of the present disclosure claimed in the following claims. Therefore, embodiments of the present disclosure are not intended to limit the technical spirit of the present disclosure, but provided only for the illustrative purpose. The scope of the present disclosure should be construed on the basis of the accompanying claims, and all the technical ideas within the scope equivalent to the claims should be included in the scope of the present disclosure.

What is claimed is:

1. A vehicle control apparatus, comprising:
a processor,
wherein the processor is configured to:
optimize a battery model based on an optimization algorithm,
generate a variable charging map based on the optimized battery model,
obtain state information of a battery,
determine an optimal charge current corresponding to the state information of the battery based on the variable charging map, and
control a charger to perform battery charging based on the determined optimal charge current.

2. The vehicle control apparatus of claim 1, wherein the optimization algorithm includes a nonlinear model predictive control algorithm.

3. The vehicle control apparatus of claim 1, wherein the battery model includes an electrochemical-thermal-life model.

4. The vehicle control apparatus of claim 1, wherein the variable charging map is a table in which an optimal charge current corresponding to a voltage and a state of health (SOH) of the battery is defined.

5. The vehicle control apparatus of claim 1, wherein the processor is configured to:
determine whether a current state of charge (SOC) of the battery is less than a fast charging upper limit SOC;
determine whether a current voltage of the battery is greater than or equal to a fast charging upper limit voltage, based on determining that the current SOC of the battery is less than the fast charging upper limit SOC; and
reduce the charge current by a predetermined factor, based on determining that the current voltage of the battery is greater than or equal to the fast charging upper limit voltage.

6. The vehicle control apparatus of claim 5, wherein the processor is configured to:
determine whether an optimization algorithm start condition is satisfied, based on determining that the current voltage of the battery is not greater than or equal to the fast charging upper limit voltage; and
execute the optimization algorithm, based on determining that the optimization algorithm start condition is satisfied.

7. The vehicle control apparatus of claim 6, wherein the processor is configured to:
determine whether a constant current application time is greater than a constant current application end time and overpotential is less than allowable overpotential; and
determine whether the optimization algorithm start condition is satisfied based on the determined result.

8. The vehicle control apparatus of claim 6, wherein the processor is configured to:
determine the optimal charge current in a predetermined constraint via the optimization algorithm.

9. The vehicle control apparatus of claim 6, wherein the processor is configured to:
maintain a previous charge current, based on determining that an optimization algorithm start condition is not satisfied.

10. The vehicle control apparatus of claim 1, wherein the processor is configured to:
obtain at least one of a voltage of the battery, a state of health (SOH) of the battery, or any combination thereof, as the state information of the battery based on one or more signals obtained from one or more sensors installed in the battery.

11. A battery charging method of a vehicle control apparatus, the battery charging method comprising:
optimizing a battery model based on an optimization algorithm;
generating a variable charging map based on the optimized battery model;
obtaining state information of a battery;
determining an optimal charge current corresponding to the state information of the battery based on the variable charging map; and
controlling a charger to perform battery charging based on the determined optimal charge current.

12. The battery charging method of claim 11, wherein the optimization algorithm includes a nonlinear model predictive control algorithm.

13. The battery charging method of claim 11, wherein the battery model includes an electrochemical-thermal-life model.

14. The battery charging method of claim 11, wherein the variable charging map is a table in which an optimal charge current corresponding to a voltage and a state of health (SOH) of the battery is defined.

15. The battery charging method of claim 11, wherein optimizing the battery model includes:
determining whether a current state of charge (SOC) of the battery is less than a fast charging upper limit SOC;
determining whether a current voltage of the battery is greater than or equal to a fast charging upper limit voltage, based on determining that the current SOC of the battery is less than the fast charging upper limit SOC; and
reducing the charge current by a predetermined factor, based on determining that the current voltage of the battery is greater than or equal to the fast charging upper limit voltage.

16. The battery charging method of claim 15, wherein optimizing the battery model includes:
determining whether an optimization algorithm start condition is satisfied, based on determining that the current voltage of the battery is not greater than or equal to the fast charging upper limit voltage; and
executing the optimization algorithm, based on determining that the optimization algorithm start condition is satisfied.

17. The battery charging method of claim 16, wherein determining whether the optimization algorithm start condition is satisfied includes:
determining whether a constant current application time is greater than a constant current application end time and overpotential is less than allowable overpotential; and
determining whether the optimization algorithm start condition is satisfied based on the determined result.

18. The battery charging method of claim 16, wherein executing the optimization algorithm includes:
determining the optimal charge current in a predetermined constraint.

19. The battery charging method of claim 16, wherein optimizing the battery model includes:
maintaining a previous charge current, based on determining that that an optimization algorithm start condition is not satisfied.

20. The battery charging method of claim 11, wherein obtaining the state information of the battery includes:
obtaining at least one of a voltage of the battery, a state of health (SOH) of the battery, or any combination thereof, as the state information of the battery based on one or more signals obtained from one or more sensors installed in the battery.
